(19) United States
(12) Patent Application Publication
(10) Pub. No.: US 2024/0243086 A1
(43) Pub. Date: Jul. 18, 2024

(54) ELECTRONIC DEVICE AND METHOD OF MANUFACTURING THE SAME

(71) Applicant: Advanced Semiconductor Engineering, Inc., Kaohsiung (TW)

(72) Inventors: Sheng-Hsiang HSU, Kaohsiung (TW); Cheng-Hung KO, Kaohsiung (TW); Jan-Feng YEN, Kaohsiung (TW)

(73) Assignee: Advanced Semiconductor Engineering, Inc., Kaohsiung (TW)

(21) Appl. No.: 18/098,395

(22) Filed: Jan. 18, 2023

(51) Int. Cl. H01L 23/00; H05K 1/18; H05K 3/34

(52) U.S. Cl. CPC H01L 24/13; H01L 24/05; H01L 24/16; H01L 24/81; H05K 1/181; H05K 3/3405; H01L 2224/0401; H01L 2224/05022; H01L 2224/05124; H01L 2224/05139; H01L 2224/05144; H01L 2224/05147; H01L 2224/05166; H01L 2224/05181; H01L 2224/13014; H01L 2224/13021; H01L 2224/13124; H01L 2224/13139; H01L 2224/13144; H01L 2224/13147; H01L 2224/13166; H01L 2224/13181; H01L 2224/13541; H01L 2224/1355; H01L 2224/13582; H01L 2224/13611; H01L 2224/13655; H01L 2224/16145; H01L 2224/16227; H01L 2224/16265; H01L 2224/16507; H10B 80/00

(57) ABSTRACT

An electronic device is disclosed. The electronic device includes a chip, a component, and a plurality of first interlayer elements. The chip has an upper surface and a first pad disposed over the upper surface. The component is disposed over the electronic component and configured to filter noise from the electronic component. The plurality of first interlayer elements connect the first pad. At least one of the plurality of the first interlayer elements is non-overlapping with the component in a direction substantially perpendicular to the upper surface of the component

### BACKGROUND

### 1. Field of the Disclosure

The present disclosure relates to an electronic device and a method of manufacturing the same.

### 2. Description of the Related Art

Passive devices may electrically connect to the power terminal of a semiconductor chip to suppress noise. However, the bond wire that conventionally connects the passive device and the semiconductor chip generally presents high resistance, which may increase the temperature of the semiconductor chip to an unacceptable level.

### SUMMARY

In some embodiments, an electronic device includes a chip, a component, and a plurality of first interlayer elements. The chip has an upper surface and a first pad disposed over the upper surface. The component is disposed over the electronic component and configured to filter noise from the electronic component. The plurality of first interlayer elements connect the first pad. At least one of the plurality of the first interlayer elements is non-overlapping with the component in a direction substantially perpendicular to the upper surface of the component.

In some embodiments, an electronic device includes a chip, a component, and a first interlayer element. The chip has a pad. The component is disposed over the chip and has a terminal. The first interlayer element is disposed over the pad and configured to guide a first connecting element to partially cover a lateral surface of the terminal.

In some embodiments, an electronic device includes a chip, a component, and a plurality of interlayer elements. The chip has a pad and an insulating layer exposing an exposed portion of the pad. The component is disposed over the chip and comprises a terminal. The plurality of interlayer elements is spaced apart from each other and disposed over the exposed portion of the pad to connect the terminal and the pad.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a top view of an electronic device in accordance with some embodiments of the present disclosure.

FIG. 1A is a cross-section of an electronic device in accordance with some embodiments of the present disclosure.

FIG. 1B is a cross-section of a portion of an electronic device in accordance with some embodiments of the present disclosure.

FIG. 1C is a cross-section of a portion of an electronic device in accordance with some embodiments of the present disclosure.

FIG. 1D is a cross-section of a portion of an electronic device in accordance with some embodiments of the present disclosure.

FIG. 2 is a top view of an electronic device in accordance with some embodiments of the present disclosure.

FIG. 2A is a cross-section of an electronic device in accordance with some embodiments of the present disclosure.

FIG. 2B is a top view of an electronic device in accordance with some embodiments of the present disclosure.

FIG. 2C is a cross-section of an electronic device in accordance with some embodiments of the present disclosure.

FIG. 2D is a top view of an electronic device in accordance with some embodiments of the present disclosure.

FIG. 2E is a cross-section of an electronic device in accordance with some embodiments of the present disclosure.

FIG. 3 is a top view of an electronic device in accordance with some embodiments of the present disclosure.

FIG. 3A is a cross-section of an electronic device in accordance with some embodiments of the present disclosure.

FIG. 3B is a cross-section of an electronic device in accordance with some embodiments of the present disclosure.

FIG. 3C is a cross-section of an electronic device in accordance with some embodiments of the present disclosure.

FIG. 3D is a top view of an electronic device in accordance with some embodiments of the present disclosure.

FIG. 3E is a cross-section of an electronic device in accordance with some embodiments of the present disclosure.

FIG. 3F is a top view of an electronic device in accordance with some embodiments of the present disclosure.

FIG. 3G is a cross-section of an electronic device in accordance with some embodiments of the present disclosure.

FIG. 3H is a cross-section of an electronic device in accordance with some embodiments of the present disclosure.

FIG. 4A illustrates one or more stages of an exemplary method for manufacturing an electronic device according to some embodiments of the present disclosure.

FIG. 4B illustrates one or more stages of an exemplary method for manufacturing an electronic device according to some embodiments of the present disclosure.

FIG. 4C illustrates one or more stages of an exemplary method for manufacturing an electronic device according to some embodiments of the present disclosure.

FIG. 4D illustrates one or more stages of an exemplary method for manufacturing an electronic device according to some embodiments of the present disclosure.

FIG. 4E illustrates one or more stages of an exemplary method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

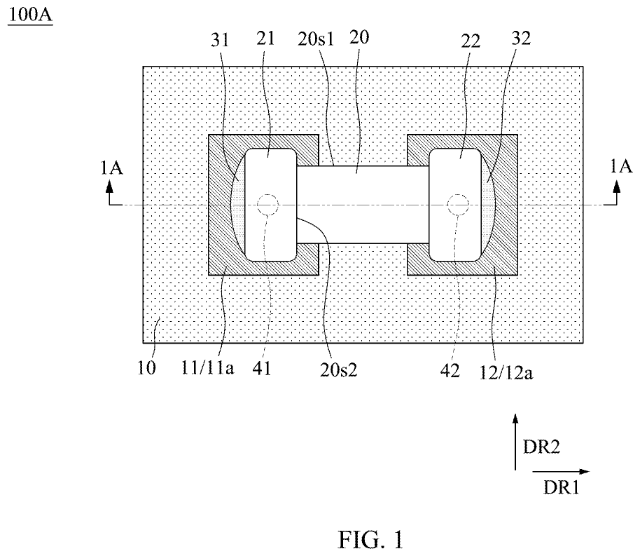

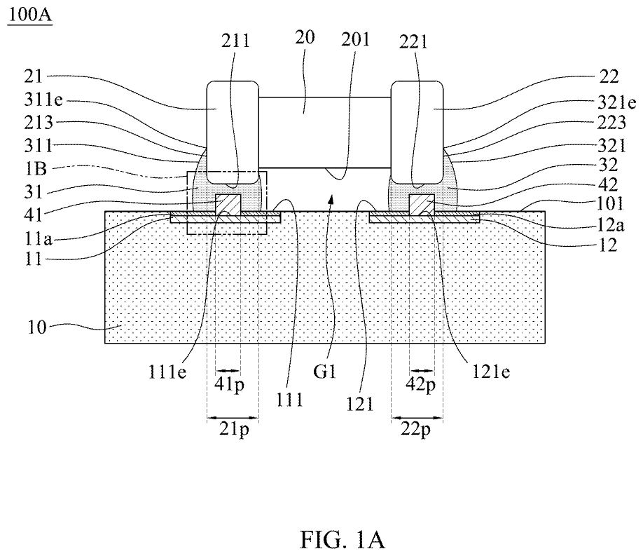

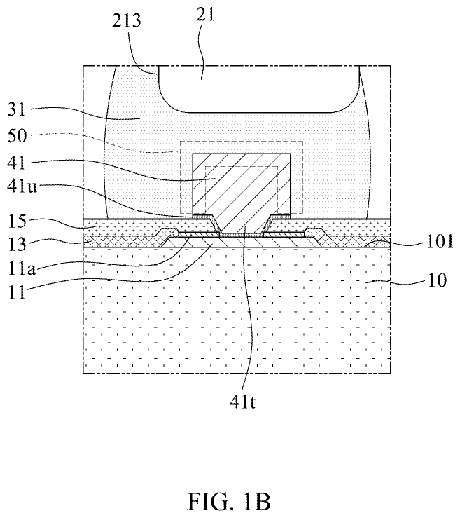

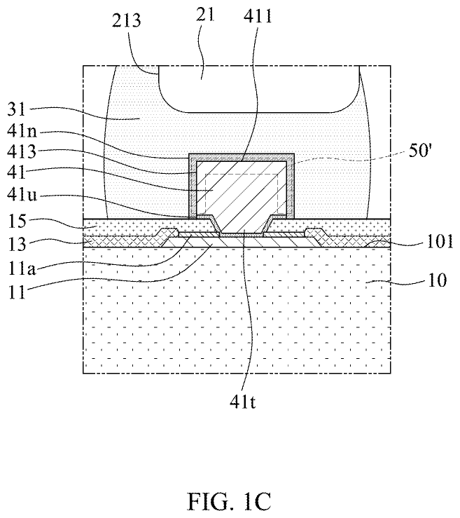

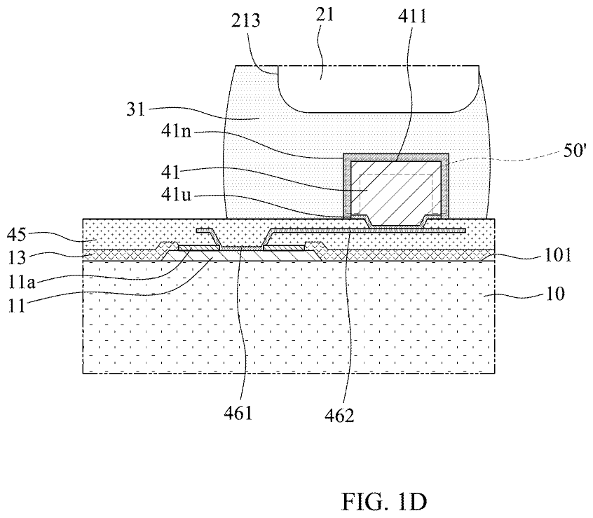

FIG. 1 is a top view of an electronic device 100A in accordance with some embodiments of the present disclosure. FIG. 1 is a cross-section of an electronic device 100A in accordance with some embodiments of the present disclosure. In some embodiments, FIG. 1A is a cross-section along line 1A-1A′ in FIG. 1. The electronic device 100A may include an electronic component 10, a component 20, connecting elements 31 and 32, and interlayer elements 41 and 42.

The electronic component 10 may have a surface 101 (an upper surface) and a surface (a lower surface) 102 opposite to the surface 101. The surface 101 may face the component 20. The electronic component 10 may include pads 11 and 12 at the surface 101. The pads 11 and 12 are physically separated. The pads 11 and 12 may have different potentials. The pad 11 may have a surface 111 substantially coplanar with the surface 101 of the electronic component 10. The pad 12 may have a surface 121 substantially coplanar with the surface 101 of the electronic component 10.

The pad 11 may include a dielectric layer 11a at the surface 111. The pad 11 may include a conductive material. The pad 11 may be formed of metal or metal alloy. The pad 11 may include metal, such as, copper, gold, silver, aluminum, titanium, tantalum, or the like. The dielectric layer 11a may be an insulating layer. The dielectric layer 11a may include a metal oxide. The dielectric layer 11a may be a chemical compound of oxide and a metal the same as that of the pad 11. In some embodiments, the pad 11 may be aluminum and the dielectric layer 11a may be aluminum oxide.

The pad 12 may include a dielectric layer 12a at the surface 121. The pad 12 may be formed of metal or metal alloy. The pad 12 may include metal, such as, copper, gold, silver, aluminum, titanium, tantalum, or the like. The dielectric layer 12a may be an insulating layer. The dielectric layer 12a may include a metal oxide. The dielectric layer 12a may be a chemical compound of oxide and a metal the same as that of the pad 12. In some embodiments, the pad 12 may be aluminum and the dielectric layer 12a may be aluminum oxide.

In some embodiments, the electronic component 10 may include a power terminal (not shown) connected to the pad 11 or the pad 12. The electronic component 10 may include a ground terminal (not shown) connected to the pad 11 or the pad 12. In some embodiments, one of the pads 11 and 12 may be referred to the power terminal of the electronic component 10 and the other of the pads 11 and 12 may be referred to the ground terminal of the electronic component 10. The electronic component 10 may include a conductive pad (not shown) at the surface 102. The conductive pad at the surface 102 may be configured to connect to an external device, carrier, or system.

In some embodiments, the electronic component 10 may include a substrate or a carrier. The electronic component 10 may include an interposer. In some embodiments, the electronic component 10 may include, for example, a printed circuit board (PCB), such as a paper-based copper foil laminate, a composite copper foil laminate, or a polymer-impregnated glass-fiber-based copper foil laminate. In some embodiments, the electronic component 10 may include a semiconductor substrate including silicon, germanium, or other suitable materials.

In some embodiments, the electronic component 10 may include a semiconductor chip. In some embodiments, the electronic component 10 and the semiconductor chip 10 may be interchangeable with respect to terminology. In some embodiments, the electronic component 10 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 10 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). The memory element may be a cache memory.

The component 20 may be disposed over the electronic component 10 (or the surface 101 of the electronic component 10). The component 20 may have a surface (an upper surface) 201 facing the surface 101 of the electronic component 10. The surface 201 of the component 20 and the surface 101 of the electronic component 10 may define a region (or a gap) G1. The component 20 may include terminals 21 and 22. The terminal 21 may have a lateral surface 213 extending in an orientation DR3 as illustrated in FIG. 1A. The lateral surface 213 may be perpendicular to the surface 201 of the component 20. The terminal 22 may have a lateral surface 223 extending along orientation DR3 as illustrated in FIG. 1A. The lateral surface 223 may be perpendicular to the surface 201 of the component 20. The terminal 21 of the component 20 may be disposed over the pad 11 of the electronic component 10. The terminal 21 may substantially align with the pad 11 of the electronic component 10. The terminal 22 of the component 20 may be disposed over the pad 12 of the electronic component 10. The terminal 22 may substantially align with the pad 12 of the electronic component 10.

The component 20 may have a longitudinal axis (or a long side or long edge) 20s1 from a top view as illustrated in FIG. 1. The longitudinal axis 20s1 may be parallel to an orientation DR1. The orientation DR1 may be perpendicular to the orientation DR3. The component 20 may have a lateral axis (or a short side or short edge) 20s2 from a top view as illustrated in FIG. 1.

The component 20 may include active devices such as transistors and/or passive devices such resistors, capacitors, inductors, or a combination thereof. For example, the component 20 may include, for example, a decoupling circuit. In some embodiments, the component 20 may be a decoupling capacitor. The component 20 may be configured to decouple the noise from the electronic component 10. For example, the component 20 may be configured to decouple the noise from a power terminal (or a power element) of the electronic component 10.

The connecting element 31 may be disposed over the pad 11 of the electronic component 10. The connecting element 31 may be disposed between the terminal 21 of the component 20 and the pad 11 of the electronic component 10. The connecting element 31 may electrically connect to the terminal 21 of the component 20 or the pad 11 of the electronic component 10. In other words, the component 20 may electrically connect to the electronic component 10 through the connecting element 31.

The connecting element 32 may be disposed over the pad 12 of the electronic component 10. The connecting element 32 may be disposed between the terminal 22 of the component 20 and the pad 12 of the electronic component 10. The connecting element 32 may electrically connect to the terminal 22 of the component 20 or the pad 12 of the electronic component 10. In other words, the component 20 may electrically connect to the electronic component 10 through the connecting element 32.

In some embodiments, the connecting elements 31 and 32 may include a conductive material. In some embodiments, the connecting elements 31 and 32 may include a metal material, e.g., tin (Sn) or alloy thereof. In some embodiments, the connecting elements 31 and 32 may include solder balls. The connecting elements 31 and 32 may be circular or elliptical from a top view as illustrated in FIG. 1. The connecting elements 31 and 32 may be circular or elliptical in cross-section as illustrated in FIG. 1A.

The interlayer element 41 may be configured to guide the connecting element 31 to partially cover the lateral surface 213 of the terminal 21. The connecting element 31 may wet the lateral surface 213 of the terminal 21. In some embodiments, the connecting element 31 may bond with a metal material of the lateral surface 213 of the terminal 21. The connecting element 31 may have a portion 311 in contact with the lateral surface 213 of the terminal 21. The portion 311 of the connecting element 31 may be circular. The portion 311 may contact the lateral surface 213 of the terminal 21 of the component 20. The portion 311 may partially cover the lateral surface 213 of the terminal 21. An end 311e of the portion 311 of the connecting element 31 may be at an elevation higher than the surface 201 of the component 20.

In some embodiments, the portion 311 of the connecting element 31 may be over a lower surface 211 of the terminal 21, and the portion 311 may have a width gradually decreasing in a direction facing away from the pad 11.

The interlayer element 42 may be configured to guide the connecting element 32 to partially cover the lateral surface 223 of the terminal 22. The connecting element 32 may wet the lateral surface 223 of the terminal 22. In some embodiments, the connecting element 32 may bond with a metal material of the lateral surface 223 of the terminal 22. The connecting element 32 may have a portion 322 in contact with the lateral surface 223 of the terminal 22. The portion 321 of the connecting element 32 may be circular. The portion 321 may contact the lateral surface 223 of the terminal 22 of the component 20. The portion 321 may partially cover the lateral surface 223 of the terminal 22. An end 322e of the portion 322 of the connecting element 32 may be at an elevation higher than the surface 201 of the component 20.

In some embodiments, the portion 321 of the connecting element 32 may be over a lower surface 221 of the terminal 22, and the portion 321 may have a width gradually decreasing in a direction facing away from the pad 12.

The interlayer element 41 may be disposed over the pad 11 of the electronic component 10. The interlayer element 41 may be disposed between the pad 11 of the electronic component 10 and the terminal 21 of the component 20. The interlayer element 41 may be surrounded by the dielectric layer 11a of the pad 11. The interlayer element 41 may contact the pad 11. The interlayer element 41 may protrude from the pad 11 (or the dielectric layer 11a). The interlayer element 41 may contact the connecting element 31. The interlayer element 41 may be surrounded by the connecting element 31. The connecting element 31 may connect the component 20 and the interlayer element 41. The interlayer element 41 may electrically connect to the pad 11 of the electronic component 10. The interlayer element 41 may electrically connect to the terminal 21 of the component 20 through the connecting element 31. The dielectric layer 11a of the pad 11 may expose an exposed portion 111e of the pad 11. The interlayer element 41 may be disposed over the exposed portion 111e of the pad 11 to connect the terminal 21 and the pad 11.

As shown in FIG. 1A, the interlayer element 41 may have a projecting area 41p on the surface 111 of the pad 11 (or the surface 101 of the electronic component 10). The terminal 21 may have a projecting area 21p on the surface 111 of the pad 11 (or the surface 101 of the electronic component 10). The projecting area 41p of the interlayer element 41 may overlap the projecting area 21p of the terminal 21. The projecting area 21p of the terminal 21 may be larger than the projecting area 41p of the interlayer element 41. The intersection of the projecting area 41p and the projecting area 21p may equal the projecting area 41p. In some embodiments, the interlayer element 41 may overlap the terminal 21 of the component 20 along orientation DR3 or perpendicular to the surface 111 of the pad 11 (or the surface 101 of the electronic component 10).

The interlayer element 42 may be disposed over the pad 12 of the electronic component 10. The interlayer element 42 may be disposed between the pad 12 of the electronic component 10 and the terminal 22 of the component 20. The interlayer element 42 may be surrounded by the dielectric layer 12a of the pad 12. The interlayer element 42 may contact the pad 12. The interlayer element 42 may protrude from the pad 12 (or the dielectric layer 12a). The interlayer element 42 may contact the connecting element 32. The interlayer element 42 may be surrounded by the connecting element 32. The connecting element 32 may connect the component 20 and the interlayer element 42. The interlayer element 42 may electrically connect to the pad 12 of the electronic component 10. The interlayer element 42 may electrically connect to the terminal 22 of the component 20 through the connecting element 32. The dielectric layer 12a of the pad 12 may expose an exposed portion 121e of the pad 12. The interlayer element 42 may be disposed over the exposed portion 121e of the pad 12 to connect the terminal 22 and the pad 12.

As shown in FIG. 1A, the interlayer element 42 may have a projecting area 42p on the surface 121 of the pad 12 (or the surface 101 of the electronic component 10). The terminal 22 may have a projecting area 22p on the surface 121 of the pad 12 (or the surface 101 of the electronic component 10). The projecting area 42p of the interlayer element 42 may overlap the projecting area 22p of the terminal 22. The projecting area 22p of the terminal 22 may exceed the projecting area 42p of the interlayer element 42. The intersection of the projecting area 42p and the projecting area 22p may equal the projecting area 42p. In some embodiments, the interlayer element 42 may overlap the terminal 22 of the component 20 along orientation DR3 or perpendicular to the surface 121 of the pad 12 (or the surface 101 of the electronic component 10).

In some embodiments, the interlayer element 41 or 42 may include an erect structure. In some embodiments, the interlayer element 41 or 42 may include a conductive pillar. The interlayer element 41 or 42 may include a conductive material. The interlayer element 41 or 42 may be formed of metal or metal alloy. The interlayer element 41 or 42 may include metal, such as, copper, gold, silver, aluminum, titanium, tantalum, or the like.

As used herein, the term, “interlayer element,” refers to any element between two layers or elements. In some embodiments, the interlayer element 41 may be between the pad 11 and the connecting element 31; the interlayer element 42 may be between the pad 12 and the connecting element 32. The interlayer elements 41 and 42 may be configured to electrically connect the electronic component 10 to the component 20. The connecting element 31 and the interlayer element 41 may be configured to electrically connect the electronic component 10 to the component 20. The connecting element 32 and the interlayer element 42 may be configured to electrically connect the electronic component 10 to the component 20.

The interlayer element 41 protruding from the pad 11 of the electronic component 10 may increase the contact area when the connecting element 31 is formed on the pad 11 of the electronic component 10. The dielectric layer 11a of the pad 11 may impede the bondability between the pad 11 and the connecting element 31. Therefore, the electronic device of the present disclosure allows the interlayer element 41 to increase the bondability between the pad 11 and the connecting element 31. Similarly, the interlayer element 42 protruding from the pad 12 of the electronic component 10 may increase the contact area when the connecting element 32 is formed on the pad 12 of the electronic component 10. The dielectric layer 12a of the pad 12 may impede the bondability between the pad 12 and the connecting element 32. Therefore, the electronic device of the present disclosure allows the interlayer element 42 to increase the bondability between the pad 12 and the connecting element 32.

Furthermore, the interlayer element 41 or 42 may extend along orientation DR3 (or perpendicular to the surface 101 of the electronic component 10). The interlayer element 41 or 42 may be a substantially erect structure (e.g., a conductive pillar), which may reduce the electrical transmission path (or resistance) between the electronic component 10 and the component 20. The erect interlayer element 41 or 42 simplifies the manufacture of the electronic device 100A and reduce required process steps and costs compared to other electronic devices which require a fan-out structure for the connection of a semiconductor die and a passive component.

In some comparative embodiments, in an electronic device, a passive component may be connected to a semiconductor chip through a bond wire. However, the bond wire has considerable length with commensurately high resistance. The high electrical resistance of the bond wire may transform a considerable amount of the electrical energy transmitted into thermal energy that increases the temperature of the electronic device. When the electronic device reaches an excessive temperature (e.g., over 125° C.), the electronic device may malfunction. In the present disclosure, the connecting elements 31 and 32 along with the interlayer elements 41 and 42 present relatively low electrical resistance and transform only a relatively small amount of electrical energy to thermal. Therefore, the temperature of the electronic device 100A can be maintained at an appropriate level (e.g., less than 50, 75, 100, or 125° C.). In some embodiments, the component 20 includes a capacitor, and the noise decoupling performed by the capacitor on the power signal from the substrate (or the electronic component) 10 can be improved.

FIG. 1B is a cross-section of a portion of an electronic device (e.g., the electronic device 100A) in accordance with some embodiments of the present disclosure. In some embodiments, the interlayer element 42 may have a structure similar to that of FIG. 1B. In some embodiments, interlayer elements 51, 51′, 51″, 52, 52′, 52″, 61, 62, 65, 66, 67, 68 which are discussed later may include other configurations similar to the conductive pillar of FIG. 1B.

In some embodiments, the conductive pillar configuration of FIG. 1B may be an enlarged view of an area 1B in FIG. 1. The configuration as illustrated in FIG. 1B may not limit the present disclosure. In some embodiments, the interlayer element 41 may include other configurations similar to the conductive pillar.

The electronic component 10 may include a passivation layer 13 and a polymer layer 15. The passivation layer 13 may be disposed over the pad 11 and the electronic component 10. The polymer layer 15 may be disposed over the passivation layer 13. The interlayer element 41 may include a conductive layer (a first conductive layer) 41u disposed over the pad 11 or between the terminal 21 and the interlayer element 41. The conductive layer 41u may contact the pad 11 of the electronic component 10. The connecting element 31 may contact the conductive layer 41u of the interlayer element 41. The conductive layer 41u of the interlayer element 41 may be surrounded by the dielectric layer 11a of the pad 11. The interlayer element 41 may include a tapered portion 41t in contact with the pad 11. The tapered portion 41t may include the conductive layer 41u along the edge of the tapered portion 41t. In some embodiments, a portion of the conductive layer 41u may be disposed along a lateral surface of the taper portion 41t.

The interlayer element 41 may have an upper surface 411 and a lateral surface 413 in contact with the connecting element 31. The interlayer element 41 may include an intermetallic compound (IMC) structure 50. The IMC structure 50 can be disposed between the interlayer element 41 and the connecting element 31. The IMC structure 50 may surround the interlayer element 41. The IMC structure 50 may enclose the interlayer element 41. The IMC structure 50 may cover the upper surface 141 of the interlayer element 41. The IMC structure 50 may surround the lateral surface 143 of the interlayer element 41. The IMC structure 50 may be formed in the interlayer element 41. The IMC structure 50 can be formed in the connecting element 31. The connecting element 31 may include the IMC structure 50.

The IMC structure 50 may result from the interaction between the connecting element 31 and the interlayer element 41. The IMC structure 50 may include a Cu, Ni, Sn combination or an Au, Sn combination. The region enclosed by the dotted lines in FIG. 1B denotes, for example but is not limited to, the topography of the IMC structure 50. The IMC structure 50 may be formed discontinuously. That is, the IMC structure 50 may be discontinuous or may not have a consistent thickness. The IMC structure 50 may increase mechanical reliability. The IMC structure 50 may improve the physical connection between the connecting element 31 and the interlayer element 41.

FIG. 1C is a cross-section of a portion of an electronic device (e.g., the electronic device 100A) in accordance with some embodiments of the present disclosure. In some embodiments, the interlayer element 42 may have a structure similar to that of FIG. 1C.

In some embodiments, the conductive pillar configuration of FIG. 1C may be an enlarged view of area 1B in FIG. 1. The configuration as illustrated in FIG. 1C may not limit the present disclosure. In some embodiments, the interlayer element 41 may include other configurations similar to the conductive pillar. In some embodiments, interlayer elements 51, 51′, 51″, 52, 52′, 52″, 61, 62, 65, 66, 67, 68 which are discussed later may include other configurations similar to the conductive pillar of FIG. 1C.

The interlayer element 41 of FIG. 1C may further include a conductive layer (e.g., a second conductive layer) 41n. The conductive layer 41n may cover the upper surface 411 and the lateral surface 413. The conductive layer 41n may cover an edge of the conductive layer 41u. The conductive layer 41n may include a metal material, such as nickel. The interlayer element 41 may include an IMC structure 50′. The conductive layer 41n may be a barrier layer between the connecting element 31 and the interlayer element 41. The conductive layer 41n may constrain the growth of the IMC structure 50′. As such, the thickness of the IMC structure 50′ can be controlled to an acceptable range, e.g., less than around 5 μm. The bondability of the interlayer element 41 and the connecting element 31 can be improved.

FIG. 1D is a cross-section of a portion of an electronic device (e.g., the electronic device 100A) in accordance with some embodiments of the present disclosure. In some embodiments, the interlayer element 42 may have a structure similar to that of FIG. 1D. In some embodiments, interlayer elements 51, 51′, 51″, 52, 52′, 52″, 61, 62, 65, 66, 67, 68 which are discussed later may include other configurations similar to the conductive pillar of FIG. 1D.

In some embodiments, the conductive pillar configuration of FIG. 1D may be an enlarged view of area 1B in FIG. 1. The configuration as illustrated in FIG. 1D may not limit the present disclosure. In some embodiments, the interlayer element 41 may include other configurations similar to the conductive pillar.

The conductive pillar configuration in FIG. 1D is similar to the conductive pillar configuration in FIG. 1C. Therefore, some detailed descriptions may refer to corresponding preceding paragraphs and are not repeated hereinafter for conciseness, with differences therebetween as follows.

As shown in FIG. 1D, a polymer layer 45 may be disposed between the interlayer element 41 and the pad 11, rather than the polymer layer 15 of FIG. 1C. A conductive layer 461 and a conductive layer 462 may be disposed in the polymer layer 45. The conductive layer 462 may be disposed over the conductive layer 461. The conductive layer 461 may be connected to the conductive layer 462. The conductive layer 461 may connect the pad 11 and the conductive layer 462 may connect the interlayer element 41. The conductive layer 461 may extend a direction substantially perpendicular to the surface 101 of the electronic component 10. The pad 11 may be non-overlapping with the interlayer element 41 in a direction substantially perpendicular to the surface 101 of the electronic component 10 (or the surface 111 of the pad 11).

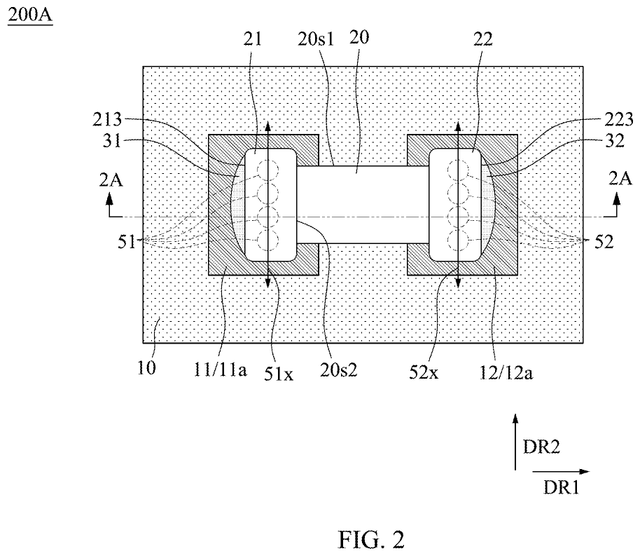

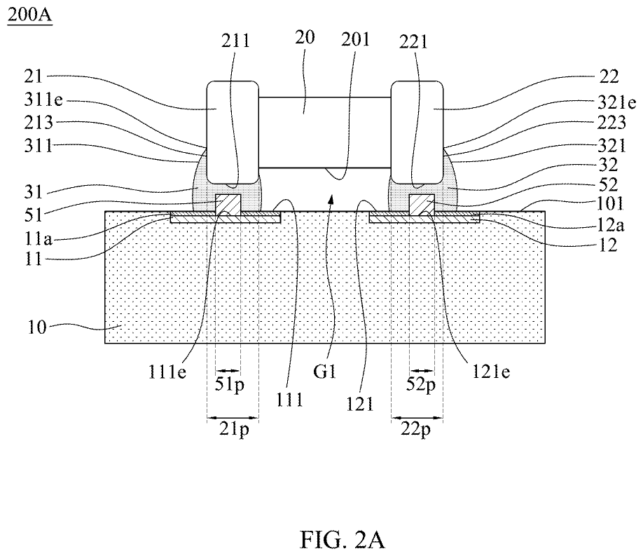

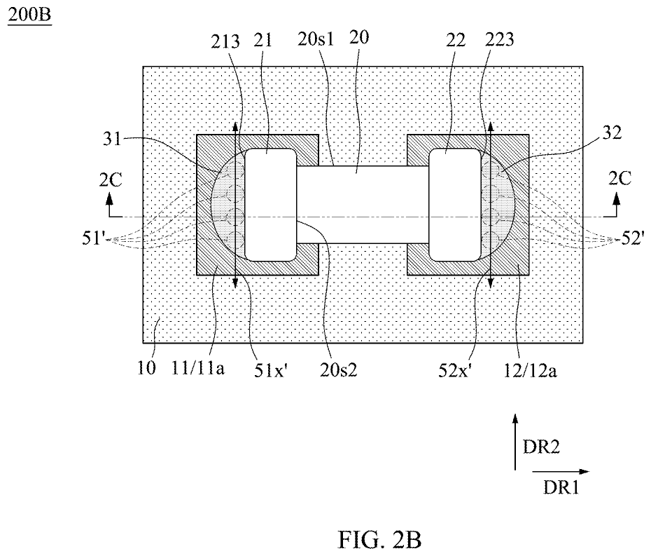

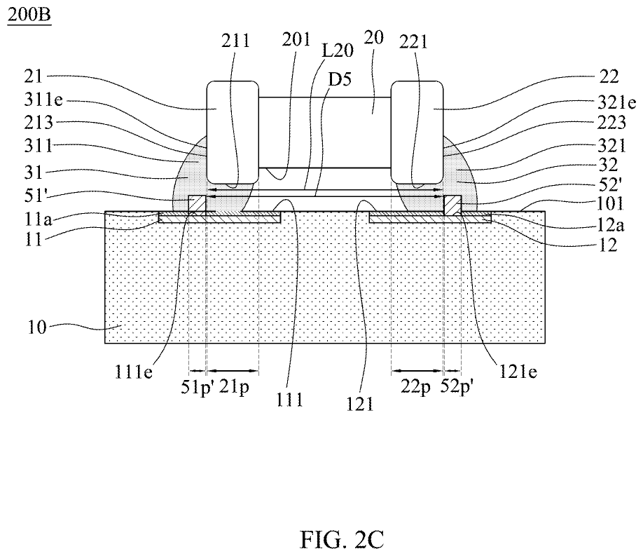

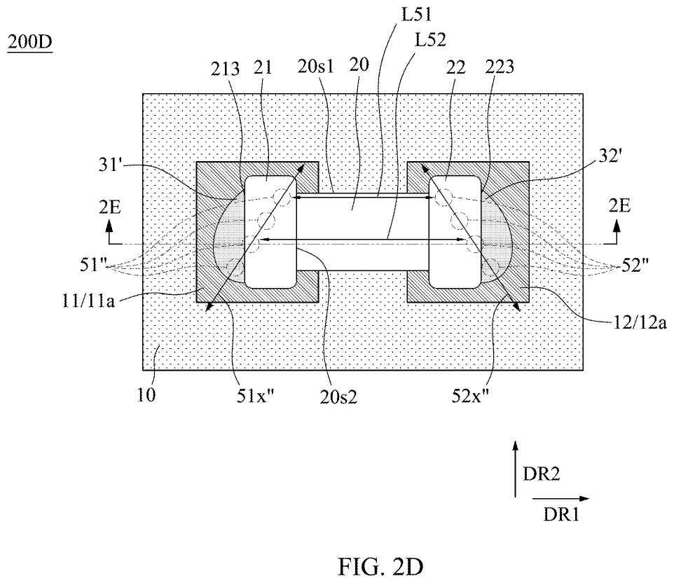

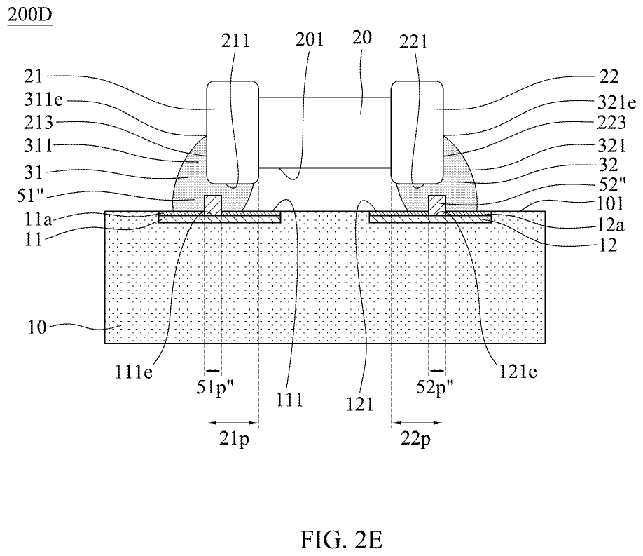

FIG. 2 is a top view of an electronic device (e.g., an electronic device 200A) in accordance with some embodiments of the present disclosure. FIG. 2A is a cross-section of an electronic device (e.g., the electronic device 200A) in accordance with some embodiments of the present disclosure. In some embodiments, FIG. 2A is a cross-section along line 2A-2A′ in FIG. 2. The electronic device 200A in FIG. 2 and FIG. 2A is similar to the electronic device 100A in FIG. 1 and FIG. 1A. Therefore, some detailed descriptions may refer to corresponding preceding paragraphs and are not repeated hereinafter for conciseness, with differences therebetween as follows.

The electronic device 200A may include a plurality of interlayer elements (or a first interlayer elements) 51 disposed over the pad 11 of the electronic component 10 and a plurality of interlayer elements (or a second interlayer elements) 52 disposed over the pad 12 of the electronic component 10. The interlayer elements 51 and 52 may be respectively electrically connected to the terminals 21 and 22 of the component 20. The interlayer elements 51 may electrically connect the terminal 21 of the component 20 and the pad 11 of the electronic component 10. The power element/ground terminal of the electronic component 10 may electrically connect to the terminal 21 of the component 20. The interlayer elements 52 may electrically connect the terminal 22 of the component 20 and the pad 12 of the electronic component 10. The power element/ground terminal of the electronic component 10 may electrically connect to the terminal 22 of the component 20. The interlayer elements 51 and the interlayer elements 52 may receive different voltages.

As shown in FIG. 2, the interlayer elements 51 are arranged in a column, wherein the column has an axis 51x substantially perpendicular to the longitudinal axis 20s1 of the component 20. The column of the interlayer elements 51 may be arranged along orientation DR3. The column of the interlayer elements 51 may be arranged parallel to the lateral surface 213 of the terminal 21 of the component 20.

The interlayer elements 51 may be disposed between the terminal 21 of the component 20 and the pad 11 of the electronic component 10. The interlayer elements 51 may be surrounded by the dielectric layer 11a of the pad 11. The interlayer elements 51 may contact the pad 11. The interlayer elements 51 may protrude from the pad 11 (or the dielectric layer 11a). The interlayer elements 51 may contact the connecting element 31. The interlayer elements 51 may be surrounded by the connecting element 31. The connecting element 31 may connect the component 20 and the interlayer elements 51. The interlayer elements 51 may electrically connect to the pad 11 of the electronic component 10. The interlayer elements 51 may electrically connect to the terminal 21 of the component 20 through the connecting element 31. The interlayer element 51 may be disposed over the exposed portion 111e of the pad 11 to connect the terminal 21 and the pad 11.

As shown in FIG. 2A, the interlayer elements 51 may have a projecting area 51p on the surface 111 of the pad 11 (or the surface 101 of the electronic component 10). The projecting area 51p of the interlayer elements 51 may overlap the projecting area 21p of the terminal 21. The projecting area 21p of the terminal 21 may exceed the projecting area 51p of the interlayer elements 51. The intersection of the projecting area 51p and the projecting area 21p may equal the projecting area 51p. In some embodiments, the interlayer elements 51 may overlap the terminal 21 of the component 20 along orientation DR3 or perpendicular to the surface 111 of the pad 11 (or the surface 101 of the electronic component 10).

As shown in FIG. 2, the interlayer elements 52 are arranged in a column, wherein the column has an axis 52x substantially perpendicular to the longitudinal axis 20s1 of the component 20. The column of the interlayer elements 52 may be arranged along orientation DR3. The column of the interlayer elements 52 may be arranged parallel to the lateral surface 223 of the terminal 22 of the component 20.

The interlayer elements 52 may be disposed between the terminal 22 of the component 20 and the pad 12 of the electronic component 10. The interlayer elements 52 may be surrounded by the dielectric layer 12a of the pad 12. The interlayer elements 52 may contact the pad 12. The interlayer elements 52 may protrude from the pad 12 (or the dielectric layer 12a). The interlayer elements 52 may contact the connecting element 32. The interlayer elements 52 may be surrounded by the connecting element 32. The connecting element 32 may connect the component 20 and the interlayer elements 52. The interlayer elements 52 may electrically connect to the pad 12 of the electronic component 10. The interlayer elements 52 may electrically connect to the terminal 22 of the component 20 through the connecting element 32. The interlayer element 52 may be disposed over the exposed portion 111e of the pad 11 to connect the terminal 22 and the pad 12.

As shown in FIG. 2A, the interlayer elements 52 may have a projecting area 52p on the surface 121 of the pad 12 (or the surface 101 of the electronic component 10). The projecting area 52p of the interlayer elements 52 may overlap the projecting area 21p of the terminal 22. The projecting area 22p of the terminal 22 may exceed the projecting area 52p of the interlayer elements 52. The intersection of the projecting area 52p and the projecting area 22p may equal the projecting area 52p. In some embodiments, the interlayer elements 52 may overlap the terminal 22 of the component 20 along orientation DR3 or perpendicular to the surface 121 of the pad 12 (or the surface 101 of the electronic component 10).

The interlayer elements 51 or 52 may be configured to guide the connecting element 31 or 32 to partially cover the lateral surface 213 of the terminal 21 or the lateral surface 223 of the terminal 22.

The plurality of interlayer elements 51 or 52 may increase the contact area for attaching the connecting element 31 or 32 to the pad 11 or 12 of the electronic component 10. In some embodiments, the connecting element 31 or 32 may be attached to the pad 11 or 12 of the electronic component 10 via surface mount technology (SMT). The interlayer elements 51 or 52 may define a larger soldered region, such that the tolerance of the offset of the SMT process of the connecting element (e.g., the solder) 31 or 32 and the component 20 can increase and a fly die issue (or a tilting of the component 20) can be avoided. The fly die issue refers to the component 20 flies away from the connecting element 31 or 32.

The interlayer elements 51 or 52 may include a conductive material. The interlayer elements 51 or 52 may be formed of metal or metal alloy. The interlayer elements 51 or 52 may include metal, such as, copper, gold, silver, aluminum, titanium, tantalum, or the like. In some embodiments, each of the interlayer elements 51 or 52 may be similar to the interlayer element 41 as illustrated in FIG. 1B or 1C.

FIG. 2B is a top view of an electronic device (e.g., an electronic device 200B) in accordance with some embodiments of the present disclosure. FIG. 2C is a cross-section of an electronic device (e.g., the electronic device 200B) in accordance with some embodiments of the present disclosure. In some embodiments, FIG. 2C is a cross-section along line 2C-2C′ in FIG. 2B. The electronic device 200B in FIG. 2B and FIG. 2C is similar to the electronic device 200A in FIG. 2 and FIG. 2A. Therefore, some detailed descriptions may refer to corresponding preceding paragraphs and are not repeated hereinafter for conciseness, with differences therebetween as follows.

The interlayer elements 51′ of the electronic device 200B may be non-overlapping with the component 20 along an axis (e.g., orientation DR3) perpendicular to the surface 111 of the pad 11 (the surface 101 of the electronic component 10). The interlayer elements 51′ may be disposed along the lateral surface 213 of the terminal 21 from a top view. The interlayer elements 51′ may be configured to electrically connect the electronic component 10 with the component 20.

The interlayer elements 52′ of the electronic device 200B may be non-overlapping with the component 20 along an axis (e.g., the orientation DR3) perpendicular to the surface 121 of the pad 12 (the surface 101 of the electronic component 10). The interlayer elements 52′ may be disposed along the lateral surface 223 of the terminal 22 from a top view. The interlayer elements 52′ may be configured to electrically connect the electronic component 10 with the component 20.

In some embodiments, a distance D5 between the interlayer elements 51′ and 52′ may exceed a length L20 of the component 20 along orientation DR1. In other words, the interlayer elements 51′ and 52′ may be disposed outside the terminals 21 and 22 of the component 20.

As shown in FIG. 2C, the interlayer elements 51′ may have a projecting area 51p′ on the surface 111 of the pad 11 (or the surface 101 of the electronic component 10). The projecting area 51p′ of the interlayer elements 51′ may be non-overlapping with the projecting area 21p of the terminal 21. The projecting area 21p of the terminal 21 may exceed the projecting area 51p′ of the interlayer elements 51. As shown in FIG. 2, the interlayer elements 51′ are arranged in a column, wherein the column has an axis 51x′ substantially perpendicular to the longitudinal axis 20s1 of the component 20. The column of the interlayer elements 51′ may be arranged along orientation DR3. The column of the interlayer elements 51′ may be arranged parallel to the lateral surface 213 of the terminal 21 of the component 20.

As shown in FIG. 2C, the interlayer elements 52′ may have a projecting area 52p′ on the surface 121 of the pad 12 (or the surface 101 of the electronic component 10). The projecting area 52p′ of the interlayer elements 52′ may be non-overlapping with the projecting area 22p of the terminal 22. The projecting area 22p of the terminal 22 may exceed the projecting area 52p′ of the interlayer elements 52. As shown in FIG. 2, the interlayer elements 52′ are arranged in a column, wherein the column has an axis 52x′ substantially perpendicular to the longitudinal axis 20s1 of the component 20. The column of the interlayer elements 52′ may be arranged along orientation DR3. The column of the interlayer elements 52′ may be arranged parallel to the lateral surface 223 of the terminal 22 of the component 20.

The interlayer elements 51′ or 52′ may be configured to guide the connecting element 31 or 32 to partially cover the lateral surface 213 of the terminal 21 or the lateral surface 223 of the terminal 22.

The plurality of interlayer elements 51′ or 52′ may increase the contact area for attaching the connecting element 31 or 32 to the pad 11 or 12 of the electronic component 10. In some embodiments, the connecting element 31 or 32 may be attached to the pad 11 or 12 of the electronic component 10 by SMT. The interlayer elements 51′ or 52′ may define a larger soldered region, such that the tolerance of the offset of the SMT process of the connecting element (e.g., the solder) 31 or 32 and the component 20 can increase and a fly die issue (or a tilting of the component 20) can be avoided. The fly die issue refers to the component 20 flies away from the connecting element 31 or 32.

FIG. 2D is a top view of an electronic device (e.g., an electronic device 200D) in accordance with some embodiments of the present disclosure. FIG. 2E is a cross-section of an electronic device (e.g., the electronic device 200D) in accordance with some embodiments of the present disclosure. In some embodiments, FIG. 2E is a cross-section along line 2E-2E′ in FIG. 2D. The electronic device 200D in FIG. 2D and FIG. 2E is similar to the electronic device 200A in FIG. 2 and FIG. 2A. Therefore, some detailed descriptions may refer to corresponding preceding paragraphs and are not repeated hereinafter for conciseness, with differences therebetween as follows.

The interlayer elements 51″ are arranged in a column, wherein the column has an axis 51x″ non-perpendicular to the longitudinal axis 20s1 of the component 20. The axis 51x″ of the interlayer elements 51″ may be non-parallel to the longitudinal axis 20s1 of the component 20. The axis 51x″ of the interlayer elements 51″ may be angled from the component 20 (or longitudinal axis 20s1). As shown in FIG. 2D, a group of the interlayer elements 51″ may overlap the terminal 21 of the component 20 along orientation DR3. One of the interlayer elements 51″ may be non-overlapping with the terminal of the component 20 along orientation DR3. As shown in FIG. 2E, one of the interlayer elements 51″ may have a projecting area 51p″ on the surface 111 of the pad 11 (or the surface 101 of the electronic component 10). The projecting area 51p″ of the interlayer elements 51″ may partially overlap the projecting area 21p of the terminal 21.

The interlayer elements 52″ are arranged in a column, wherein the column has an axis 52x″ non-perpendicular to the longitudinal axis 20s1 of the component 20. The axis 52x″ of the interlayer elements 52″ may be non-parallel to the longitudinal axis 20s1 of the component 20. The axis 52x″ of the interlayer elements 52″ may be angled from the component 20 (or the lengthwise 20s1). As shown in FIG. 2D, a group of the interlayer elements 52″ may overlap the terminal 22 of the component 20 along orientation DR3. One of the interlayer elements 52″ may be non-overlapping with the terminal of the component 20 along orientation DR3. As shown in FIG. 2E, one of the interlayer elements 52″ may have a projecting area 52p″ on the surface 121 of the pad 12 (or the surface 101 of the electronic component 10). The projecting area 52p″ of the interlayer elements 52″ may partially overlap the projecting area 22p of the terminal 22.

In some embodiments, the column of the interlayer elements 51″ and the column of the interlayer elements 52″ may extend along substantially the same axis. In alternative embodiments, the column of the interlayer elements 51″ and the column of the interlayer elements 52″ may extend along different axes.

The interlayer elements 51″ or 52″ may be configured to guide the connecting element 31 or 32 to partially cover the lateral surface 213 of the terminal 21 or the lateral surface 223 of the terminal 22.

The plurality of interlayer elements 51″ or 52″ may increase the contact area for attaching the connecting element 31 or 32 to the pad 11 or 12 of the electronic component 10. In some embodiments, the connecting element 31 or 32 may be attached to the pad 11 or 12 of the electronic component 10 by SMT. The interlayer elements 51″ or 52″ may define a larger soldered region, such that the tolerance of the offset of the SMT process of the connecting element (e.g., the solder) 31 or 32 and the component 20 can increase and a fly die issue (or a tilting of the component 20) can be avoided. The fly die issue refers to the component 20 flies away from the connecting element 31 or 32.

Furthermore, a distance between each of the interlayer elements 51″ and the corresponding interlayer element 52″ may be varied. In other words, a first distance (e.g., a distance D51) between a first of the interlayer elements 51″ and a first of the interlayer elements 52″ may be shorter than a second distance (e.g., a distance D52) between a second of the interlayer elements 51″ and a second of the interlayer elements 52″. The opposite oblique configuration of the interlayer elements 51″ and 52″ increases the tolerance of the offset of the SMT process of the connecting element (e.g., the solder) 31 or 32 and the component 20 can increase.

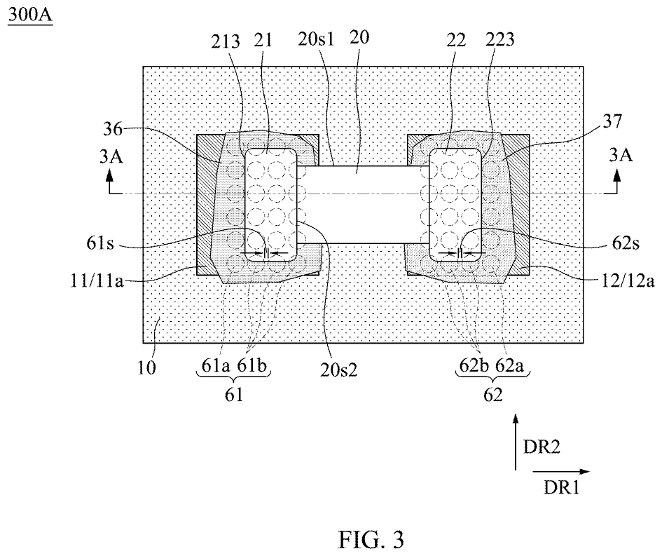

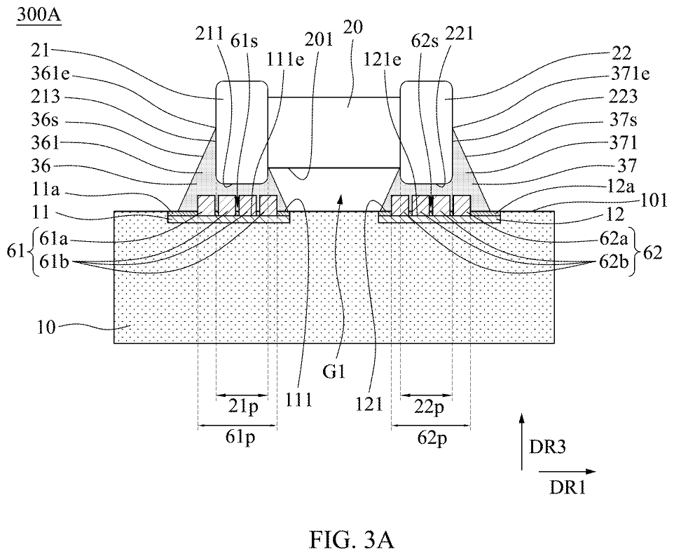

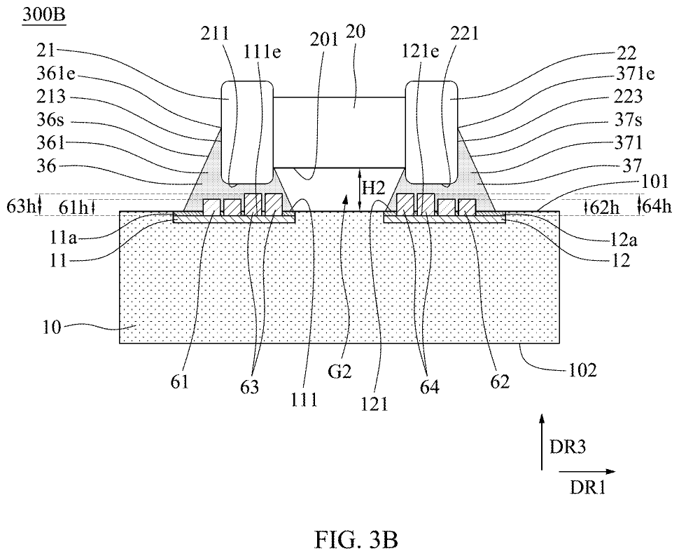

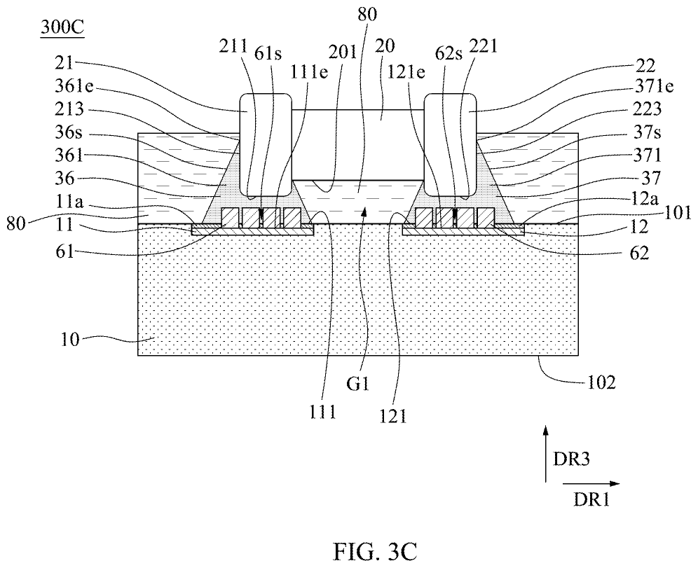

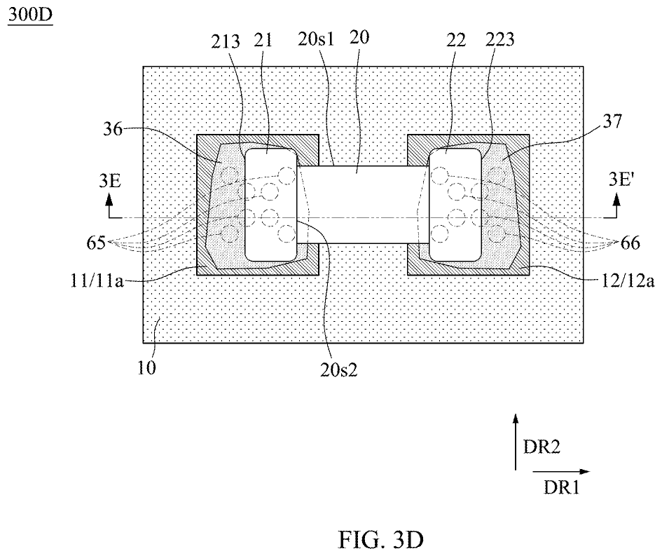

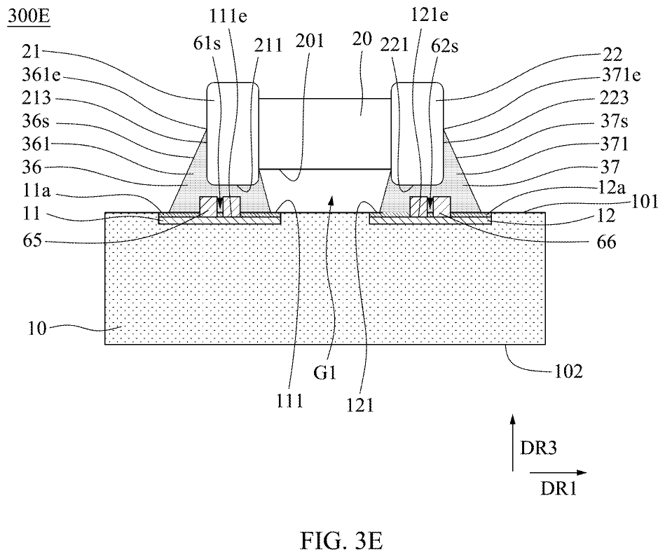

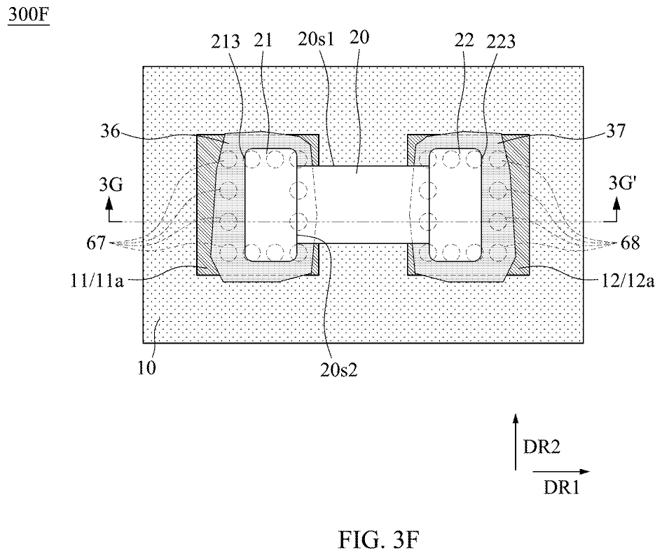

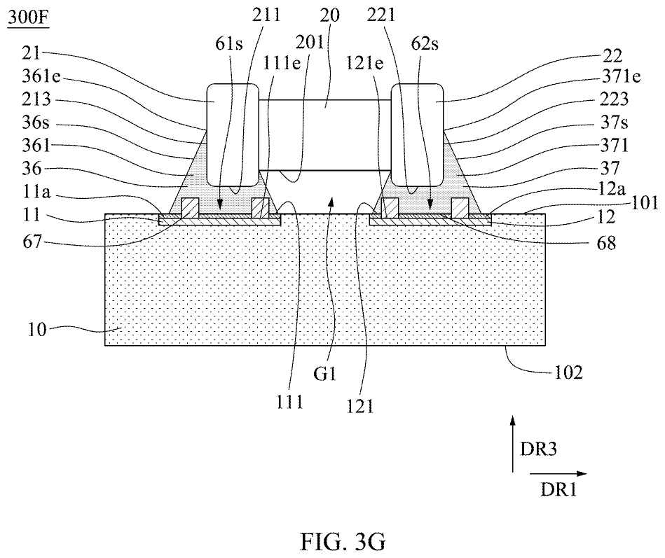

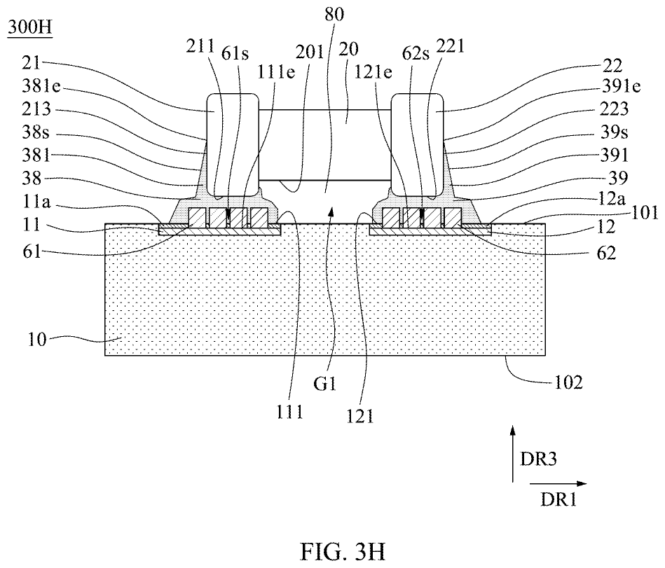

FIG. 3 is a top view of an electronic device (e.g., an electronic device 300A) in accordance with some embodiments of the present disclosure. FIG. 3A is a cross-section of an electronic device (e.g., the electronic device 300A) in accordance with some embodiments of the present disclosure. In some embodiments, FIG. 3A is a cross-section along line 3A-3A′ in FIG. 3. The electronic device 300A in FIG. 3 and FIG. 3A is similar to the electronic device 200A in FIG. 2 and FIG. 2A. Therefore, some detailed descriptions may refer to corresponding preceding paragraphs and are not repeated hereinafter for conciseness, with differences therebetween as follows.

The electronic device 300A may include a plurality of interlayer elements (or a first interlayer element) 61 disposed over the pad 11 of the electronic component 10 and a plurality of interlayer elements (or a second interlayer element) 62 disposed over the pad 12 of the electronic component 10. The interlayer elements 61 and 62 may be respectively electrically connected to the terminals 21 and 22 of the component 20. The interlayer elements 61 may electrically connect the terminal 21 of the component 20 and the pad 11 of the electronic component 10. The power terminal/ground terminal of the electronic component 10 may electrically connect to the terminal 21 of the component 20. The interlayer elements 62 may electrically connect the terminal 22 of the component 20 and the pad 12 of the electronic component 10. The power terminal/ground terminal of the electronic component 10 may electrically connect to the terminal 22 of the component 20. The interlayer elements 61 and the interlayer elements 62 may receive different voltages.

The interlayer elements 61 may be disposed between the terminal 21 of the component 20 and the pad 11 of the electronic component 10. The interlayer elements 61 may be surrounded by the dielectric layer 11a of the pad 11. The interlayer element 61 may be disposed over the exposed portion 111e of the pad 11 to connect the terminal 21 and the pad 11. The plurality of the interlayer elements 61 may be physically separated. The plurality of the interlayer elements 61 may be spaced apart from each other. The two adjacent interlayer elements 61 may be spaced apart by a space 61s. A portion of the connecting element 36 may be disposed between two of the adjacent interlayer elements 61. The interlayer elements 61 may contact the pad 11. The interlayer elements 61 may protrude from the pad 11 (or the dielectric layer 11a). The interlayer elements 61 may contact the connecting element 36. The interlayer elements 61 may be surrounded by the connecting element 36. The connecting element 36 may be wider at a first end in contact with the pad 11 than a second end in contact with the terminal 21. In some embodiments, a distance between a lateral surface 36s of the connecting element 36 and the lateral surface 213 of the terminal 21 may increase in a direction toward the lower surface 211 of the terminal 21.

The connecting element 36 may connect the component 20 and the interlayer elements 61. The interlayer elements 61 may electrically connect to the pad 11 of the electronic component 10. The interlayer elements 61 may electrically connect to the terminal 21 of the component 20 through the connecting element 36.

The interlayer elements 61 may have a group 61a non-overlapping with the component 20 (or the terminal 21) perpendicular to the upper surface 101 of the electronic component 10. In other words, at least one of the interlayer elements 61 may be non-overlapping with the electronic component 10 in a direction substantially perpendicular to the upper surface 101 of the electronic component 10. The interlayer elements 61 may have a group 61b partially overlapping the component 20 (or the terminal 21) perpendicular to the upper surface 101 of the electronic component 10. The group 61b may be closer to the component 20 than the group 61a. At least one of the group 61a of the interlayer elements 61 may be electrically connected to at least one of the group 61b of the interlayer elements 61 through the pad 11. A number of the group 61b of the interlayer elements 61 may be greater than that of the group 61a of the interlayer elements 61.

As shown in FIG. 3, the interlayer elements 61 may be arranged in an array configuration. The interlayer elements 61 may be arranged in array configuration and along and adjacent to the lateral surface (or the side) 213 of the terminal 21 of the component 20. The array configuration of the interlayer elements 61 may have a projecting area 61p on the surface 111 of the pad 11 (or the surface 101 of the electronic component 10). The projecting area 61p of the interlayer elements 61 may overlap the projecting area 21p of the terminal 21. The projecting area 21p of the terminal 21 may exceed the projecting area 61p of the interlayer elements 61. The intersection of the projecting area 61p and the projecting area 21p may equal the projecting area 21p. In some embodiments, the interlayer elements 61 may overlap the terminal 21 of the component 20 along orientation DR3 or perpendicular to the surface 111 of the pad 11 (or the surface 101 of the electronic component 10).

The interlayer elements 62 may be disposed between the terminal 22 of the component 20 and the pad 12 of the electronic component 10. The interlayer elements 62 may be surrounded by the dielectric layer 12a of the pad 12. The interlayer element 62 may be disposed over the exposed portion 121e of the pad 12 to connect the terminal 22 and the pad 12. The plurality of the interlayer elements 62 may be physically separated. The two adjacent interlayer elements 62 may be spaced apart by a space 62s. A portion of the connecting element 36 may be disposed between two of the adjacent interlayer elements 62. The interlayer elements 62 may contact the pad 12. The interlayer elements 62 may protrude from the pad 12 (or the dielectric layer 12a). The interlayer elements 62 may contact the connecting element 36. The interlayer elements 62 may be surrounded by the connecting element 36. The connecting element 37 may be wider at a first end in contact with the pad 12 than a second end in contact with the terminal 22. In some embodiments, a distance between a lateral surface 37s of the connecting element 37 and the lateral surface 223 of the terminal 22 may increase in a direction toward the lower surface 221 of the terminal 22.

The connecting element 36 may connect the component 20 and the interlayer elements 62. The interlayer elements 62 may electrically connect to the pad 12 of the electronic component 10. The interlayer elements 62 may electrically connect to the terminal 22 of the component 20 through the connecting element 36.

The interlayer elements 62 may have a group 62a non-overlapping with the component 20 (or the terminal 22) perpendicular to the upper surface 101 of the electronic component 10. In other words, at least one of the interlayer elements 62 may be non-overlapping with the electronic component 10 in a direction substantially perpendicular to the upper surface 101 of the electronic component 10. The interlayer elements 62 may have a group 62b partially overlapping the component 20 (or the terminal 22) perpendicular to the upper surface 101 of the electronic component 10. At least one of the group 62a of the interlayer elements 62 may be electrically connected to at least one of the group 62b of the interlayer elements 62 through the pad 12.

As shown in FIG. 3, the interlayer elements 62 may be arranged in an array configuration. The interlayer elements 62 may be arranged in array configuration and along and adjacent to the lateral surface (or the side) 223 of the terminal 22 of the component 20. The array configuration of the interlayer elements 62 may have a projecting area 62p on the surface 121 of the pad 12 (or the surface 101 of the electronic component 10). The projecting area 62p of the interlayer elements 62 may overlap the projecting area 22p of the terminal 22. The projecting area 22p of the terminal 22 may exceed the projecting area 62p of the interlayer elements 62. The intersection of the projecting area 62p and the projecting area 22p may equal the projecting area 22p. In some embodiments, the interlayer elements 62 may overlap the terminal 22 of the component 20 along orientation DR3 or perpendicular to the surface 121 of the pad 12 (or the surface 101 of the electronic component 10).

The interlayer elements 61 and 62 may have advantages or technical effects similar to those for the interlayer elements 41 and 42 as well as the interlayer elements 51 and 52. For example, the interlayer elements 61 and 62 may improve the bondability between the connecting elements 36 and 37 and the electronic component 10. The interlayer elements 61 and 62 may have relatively low electrical resistance and the temperature of the electronic device 300A can be maintained at an acceptable level. The component 20 includes a capacitor, and the noise decoupling performed by the capacitor on the power signal from the substrate (or the electronic component) 10 can be improved. Furthermore, the interlayer elements 61 and 62 may increase the contact area (or the soldered region), such that the tolerance of the offset of the SMT process of the connecting element (e.g., the solder) 36 or 37 and the component 20 can increase and a fly die issue (or a tilting of the component 20) can be avoided.

The array configuration of the interlayer elements 61 and 62 may alter the topography of the connecting elements 36 and 37. As shown in FIG. 3, the connecting elements 36 and 37 may have an irregular shape (or perimeter). During the reflow process of the connecting elements 36 and 37, the array configuration of the interlayer elements 61 and 62 may hold a portion of the material of the connecting elements 36 and 37. Specifically, the group 61a of the interlayer elements 61 and the group 62a of the interlayer elements 62 respectively non-overlapping with the terminals 21 and 22 along orientation DR3 may make the connecting elements 36 and 37 extend outwardly beyond the terminals 21 and 22 from a top view. In some embodiments, the connecting elements 36 and 37 may cover nearly the whole surface 111 of the pad 11 and the whole surface 121 of the pad 12.

The interlayer elements 61 may be configured to guide the connecting element 36 to partially cover the lateral surface 213 of the terminal 21. The connecting element 36 may wet the lateral surface 213 of the terminal 21. In some embodiments, the connecting element 36 may bond with a metal material of the lateral surface 213 of the terminal 21. As shown in FIG. 3A, the connecting element 36 may have a portion 361 being trapezoidal. The portion 361 may contact the lateral surface 213 of the terminal 21 of the component 20. The portion 361 may partially cover the lateral surface 213 of the terminal 21. The portion 361 may have a substantially angled surface (or tilted surface or lateral surface) 36s. An end 361e of the portion 361 of the connecting element 36 may be at an elevation higher than the surface 201 of the component 20.

In some embodiments, the portion 361 of the connecting element 36 may be over a lower surface 211 of the terminal 21, and the portion 361 may have a width gradually decreasing in a direction facing away from the pad 11.

The interlayer elements 62 may be configured to guide the connecting element 37 to partially cover the lateral surface 223 of the terminal 22. The connecting element 37 may wet the lateral surface 223 of the terminal 22. In some embodiments, the connecting element 37 may bond with a metal material of the lateral surface 223 of the terminal 22. The connecting element 37 may have a portion 371 being trapezoidal. The portion 371 may contact the lateral surface 223 of the terminal 22 of the component 20. The portion 371 may partially cover the lateral surface 223 of the terminal 22. The portion 371 may have a substantially angled surface (or tilted surface) 37s. An end 371e of the portion 371 of the connecting element 37 may be at an elevation higher than the surface 201 of the component 20.

In some embodiments, the portion 371 of the connecting element 37 may be over a lower surface 221 of the terminal 22, and the portion 371 may have a width gradually decreasing in a direction facing away from the pad 12.

In some comparative embodiments, solder may generally have a round shape between a substrate and a component. The round shape of the solder indicates that the soldered area is narrower than the component 20, impeding automated optical inspection (AOI). In the present disclosure, the substantially angled surface 36s of the connecting element 36 and the substantially angled surface 37s of the connecting element 37 can facilitate the optical inspection (e.g., AOI). The substantially angled surfaces 36s and 37s of the connecting elements 36 and 37 accurately reflect the bondability (e.g., the solder joint quality in the case of solder) between the connecting elements 36 and 37 and the electronic component 10.

The interlayer elements 61 or 62 may include a conductive material. The interlayer elements 61 or 62 may be formed of metal or metal alloy. The interlayer elements 61 or 62 may include metal, such as, copper, gold, silver, aluminum, titanium, tantalum, or the like. In some embodiments, each of the interlayer elements 61 or 62 may be similar to the interlayer element 41 as illustrated in FIG. 1B or 1C.

FIG. 3 illustrate an embodiment in which the array of the interlayer elements 61 or 62 may be 4 (row) by 6 (column). In some embodiments, the array of the interlayer elements 61 or 62 may be 3 by 4, 4 by 5, or 7 by 9, etc. The space 61s or 62s may be around 20 μm.

FIG. 3B is a cross-section of an electronic device (e.g., an electronic device 300B) in accordance with some embodiments of the present disclosure. The electronic device 300B in FIG. 3B is similar to the electronic device 300A in FIG. 3 and FIG. 3A. Therefore, some detailed descriptions may refer to corresponding preceding paragraphs and are not repeated hereinafter for conciseness, with differences therebetween as follows.

The electronic device 300B may further include a plurality of interlayer elements 63 having a height 63h greater than a height 61h of the interlayer elements 61. The interlayer elements 63 may be closer to the component 20 than the interlayer elements 61. The electronic device 300B may further include a plurality of interlayer elements 64 having a height 64h greater than a height 62h of the interlayer elements 62. The interlayer elements 64 may be closer to the component 20 than the interlayer elements 62.

Referring again to FIG. 3A, the region G1 defined by the lower surface 201 of the component 20 and the upper surface 101 of the electronic component 10 has a height H1. Alternatively, as shown in FIG. 3B, the lower surface 201 of the component 20 and the upper surface 101 of the electronic component 10 may define a region G2 having a height H2. The height H2 may exceed the height H1. During the formation of a molding material onto the electronic device 300B, the region G1 or G2 may be filled with a molding material without a void.

FIG. 3C is a cross-section of an electronic device in accordance with some embodiments of the present disclosure. The electronic device 300C in FIG. 3C is similar to the electronic device 300A in FIG. 3 and FIG. 3A. Therefore, some detailed descriptions may refer to corresponding preceding paragraphs and are not repeated hereinafter for conciseness, with differences therebetween as follows.

The electronic device 300C may further include a protective element (or an encapsulant 80) disposed over the surface 101 of the electronic component 10. The protective element 80 may cover the connecting elements 36 and 37. The protective element 80 may surround the component 20. A portion of the protective element 80 may be disposed in the gap G1. The gap G1 may be filled with the protective element 80. During the formation of the protective element 80 onto the electronic device 300C, the region G1 may be filled with a molding material without a void. In some embodiments, the protective element 80 may include an epoxy resin including fillers, a molding compound (e.g., an epoxy molding compound or other molding compound), polyimide, a phenolic compound or material, a material including silicone dispersed therein, or a combination thereof.

FIG. 3D is a top view of an electronic device (e.g., an electronic device 300D) in accordance with some embodiments of the present disclosure. FIG. 3E is a cross-section of an electronic device (e.g., the electronic device 300D) in accordance with some embodiments of the present disclosure. In some embodiments, FIG. 3E is a cross-section along line 3E-3E′ in FIG. 3D. The electronic device 300D in FIG. 3D and FIG. 3E is similar to the electronic device 300A in FIG. 3 and FIG. 3A. Therefore, some detailed descriptions may refer to corresponding preceding paragraphs and are not repeated hereinafter for conciseness, with differences therebetween as follows.

The electronic device 300D may include a plurality of interlayer elements 65 in a cross configuration disposed over the pad 11 of the electronic component 10. The electronic device 300D may include a plurality of interlayer elements 66 in a cross configuration disposed over the pad 12 of the electronic component 10. The interlayer elements 65 and 66 may have advantages or technical effects similar to those for the interlayer elements 61 and 62 as previously discussed. For example, the interlayer elements 65 or 66 may be configured to guide the connecting element 36 or 37 to partially cover the lateral surface 213 of the terminal 21 or the lateral surface 223 of the terminal 22. The interlayer elements 65 and 66 may increase the soldered area and alter the connecting elements 36 and 37 to have substantially angled surfaces.

FIG. 3F is a top view of an electronic device (e.g., an electronic device 300F) in accordance with some embodiments of the present disclosure. FIG. 3G is a cross-section of an electronic device in accordance with some embodiments of the present disclosure. In some embodiments, FIG. 3G is a cross-section along line 3G-3G′ in FIG. 3G. The electronic device 300F in FIG. 3F and FIG. 3G is similar to the electronic device 300A in FIG. 3 and FIG. 3A. Therefore, some detailed descriptions may refer to corresponding preceding paragraphs and are not repeated hereinafter for conciseness, with differences therebetween as follows.

The electronic device 300F may include a plurality of interlayer elements 67 in a pane (or square frame) configuration disposed over the pad 11 of the electronic component 10. The electronic device 300F may include a plurality of interlayer elements 68 in a pane (or square frame) configuration disposed over the pad 12 of the electronic component 10. The interlayer elements 67 and 68 may have advantages or technical effects similar to those of the interlayer elements 61 and 62 as previously discussed. For example, the interlayer elements 67 or 68 may be configured to guide the connecting element 36 or 37 to partially cover the lateral surface 213 of the terminal 21 or the lateral surface 223 of the terminal 22. The interlayer elements 67 and 68 may increase the soldered area and alter the connecting elements 36 and 37 to have substantially angled surfaces.

FIG. 3H is a cross-section of an electronic device (e.g., an electronic device 300H) in accordance with some embodiments of the present disclosure. The electronic device 300H in FIG. 3H is similar to the electronic device 300A in FIG. 3 and FIG. 3A. Therefore, some detailed descriptions may refer to corresponding preceding paragraphs and are not repeated hereinafter for conciseness, with differences therebetween as follows.

The electronic device 300H may include a connecting element 38 disposed between the terminal 21 of the component 20 and the pad 11 of the electronic component 10. The connecting element 38 may connect the terminal 21 and the pad 11. The interlayer elements 61 may be configured to guide the connecting element 38 to partially cover the lateral surface 213 of the terminal 21. The connecting element 38 may have a portion 381 partially covering the lateral surface 213 of the terminal 21. The connecting element 38 may have a lateral surface 38s having a plurality of sections with different slopes. As shown in FIG. 3H, the lateral surface 38s may have an upper section with a relatively large slope, a middle section with a relatively small slope, and a lower section with a relatively large slope. The middle section may connect the upper section and the lower section. The upper section may be closer to the terminal 21 than to the pad 11. The lower section may be closer to the pad 11 than to the terminal 21.

The electronic device 300H may include a connecting element 39 disposed between the terminal 22 of the component 20 and the pad 12 of the electronic component 10. The connecting element 39 may connect the terminal 22 and the pad 12. The interlayer elements 62 may be configured to guide the connecting element 39 to partially cover the lateral surface 223 of the terminal 22. The connecting element 39 may have a portion 391 partially covering the lateral surface 223 of the terminal 22. The connecting element 39 may have a lateral surface 39s having a plurality of sections with different slopes. As shown in FIG. 3H, the lateral surface 39s may have an upper section with a relatively large slope, a middle section with a relatively small slope, and a lower section with a relatively large slope. The middle section may connect the upper section and the lower section. The upper section may be closer to the terminal 22 than to the pad 12. The lower section may be closer to the pad 12 than to the terminal 22.

The connecting elements 38 and 39 may each have a profile substantially conformal to the distribution of the interlayer elements 61 and 62, respectively. As such, the connecting elements 38 and 39 can facilitate the optical inspection (e.g., AOI).

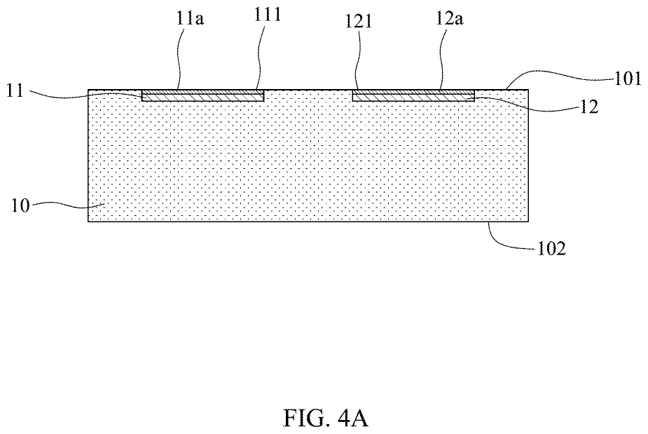

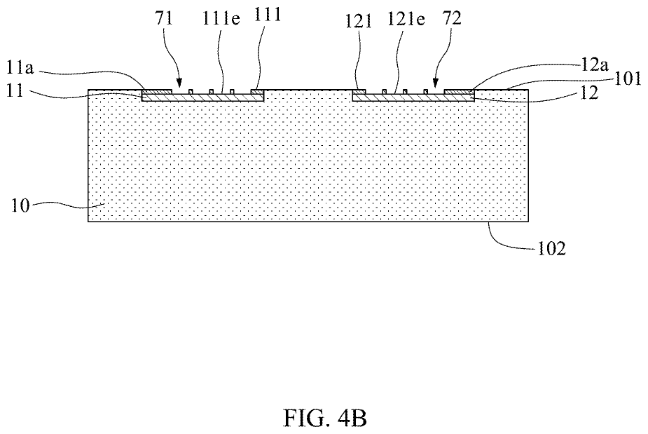

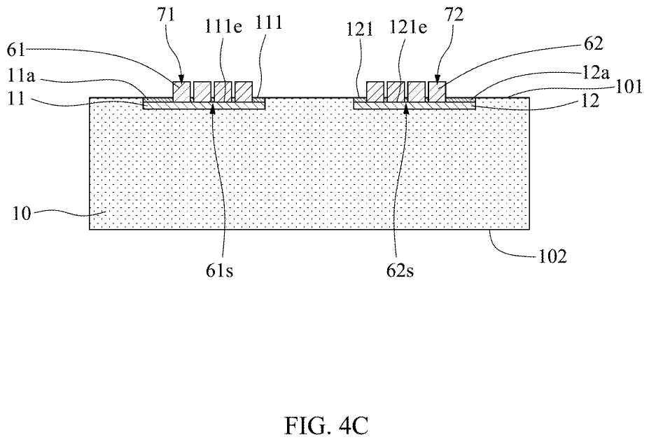

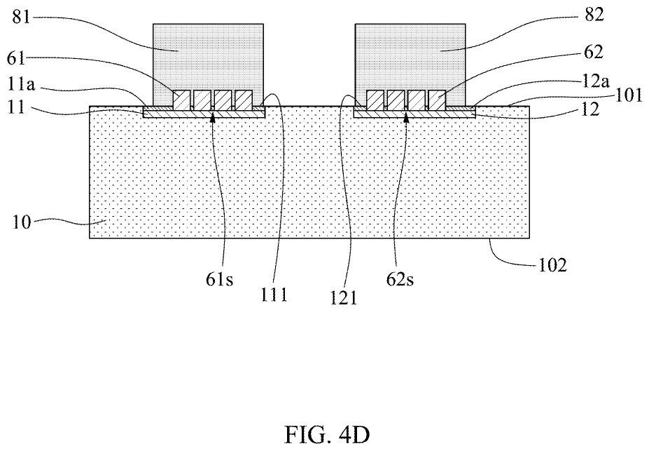

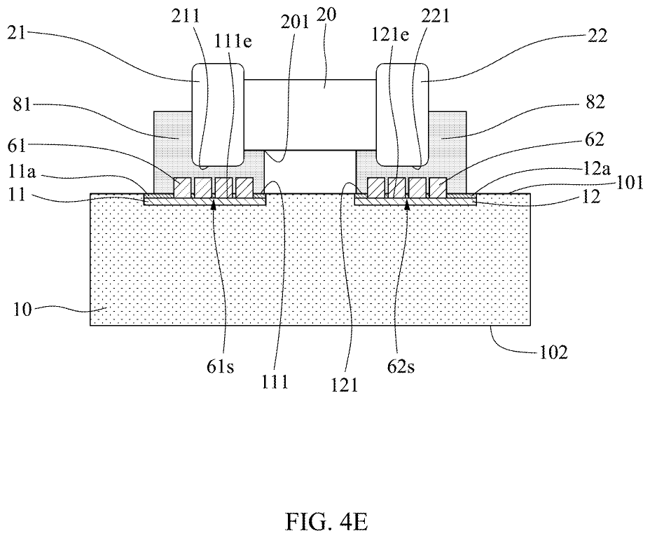

FIGS. 4A, 4B, 4C, 4D, and 4E illustrate a method for manufacturing an electronic device according to some embodiments of the present disclosure. In some embodiments, the method manufactures the electronic device 300A. In some embodiments, the electronic devices 100A, 200A, 200B, 200D, 300B, 300C, 300D, and 300F may be manufactured in a method similar to the method illustrated in FIGS. 4A-4E.

As shown in FIG. 4A, a substrate (or a semiconductor chip) 10 may be provided. Pads 11 and 12 may be formed at a surface 101 of the electronic component 10. The electronic component 10 may have a surface 102 opposite to the surface 101. The surface 102 may be configured to electrically connect to an external device, system, etc. The pad 11 may include a dielectric layer 11a at a surface 111 of the pad 11. The pad 12 may include a dielectric layer 12a at a surface 121 of the pad 12. The dielectric layer 11a or 12a may be formed by autoxidation.

As shown in FIG. 4B, a plurality of openings 71 and 72 may be respectively formed over the pads 11 and 12. The openings 71 may be in the dielectric layer 11a. An exposed portion 111e of the pad 11 may be exposed by the openings 71. The openings 72 may be in the dielectric layer 11b. An exposed portion 121e of the pad 12 may be exposed by the openings 72.

As shown in FIG. 4C, a plurality of interlayer elements 61 and 62 may be respectively formed in the openings 71 and 72. The interlayer elements 61 may contact the conductive material of the exposed portion 111e of the pad 11 and the interlayer elements 62 may contact the conductive material of the exposed portion 121e of the pad 12. The interlayer elements 61 may be spaced apart by 61s and the interlayer elements 62 may be spaced apart by 62s. In some embodiments, the interlayer elements 61 and 62 may have an array configuration.

As shown in FIG. 4D, a connection material 81 may be formed on the pad 11 to encapsulating the interlayer elements 61 and a connection material 82 may be formed on the pad 12 to encapsulating the interlayer elements 62. In some embodiments, the connection material 81 and 82 may each include solder paste printed on the pads 11 and 12.

As shown in FIG. 4E, a component 20 having terminals 21 and 22 may be attached to the electronic component 10. The terminals 21 and 22 may be respectively attached to the connection materials 81 and 82. The interlayer elements 61 and 62 can increase the jointed area (e.g., the soldered area), such that the tolerance of the offset of the SMT process of the connecting element (e.g., the solder) 36 or 37 and the component 20 can increase and a fly die issue (or a tilting of the component 20) can be avoided. Afterwards, a reflow process may be performed to transform the connection material 81 and 82 to the connecting elements 36 and 37 as shown in FIG. 3A. Owing to the interlayer elements 61 and 62, the connecting elements 36 and 37 have substantially angled surface 36s and 37s, which facilitate the AOI test for, e.g., the bondability of the connecting elements 36, 37 and the component 20.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a chip having an upper surface and a first pad disposed over the upper surface;
a component disposed over the chip and configured to filter noise from the chip; and
a plurality of first interlayer elements connecting the first pad, wherein at least one of the plurality of the first interlayer elements is non-overlapping with the component in a direction substantially perpendicular to the upper surface of the component.

2. The electronic device of claim 1, wherein the plurality of the first interlayer elements are spaced apart from each other.

3. The electronic device of claim 1, further comprising a plurality of second interlayer elements disposed over a second pad of the chip, wherein the component comprises a first terminal electrically connected to the first interlayer elements and a second terminal electrically connected to the second interlayer elements.

4. The electronic device of claim 1, further comprising a first connecting element connecting the component and the first interlayer elements.

5. The electronic device of claim 4, wherein a portion of the first connecting element is disposed between two of the adjacent first interlayer elements.

6. The electronic device of claim 1, wherein the component has a first terminal, and the first interlayer elements are arranged in array configuration and extending along a side of the first terminal of the component in a top view perspective.

7. The electronic device of claim 1, wherein the first interlayer elements are arranged in a column, wherein the column has an axis substantially perpendicular to a longitudinal axis of the component.

8. The electronic device of claim 4, wherein the component has a first terminal, and a portion of the first connecting element is in contact with a lateral surface of the first terminal.

9. The electronic device of claim 1, wherein the first interlayer elements has a first group overlapping the component in the direction substantially perpendicular to the upper surface of the component and a second group non-overlapping with the component in the direction substantially perpendicular to the upper surface of the component, and wherein a first number of the first group of the first interlayer elements is greater than a second number of the second group of the first interlayer elements.

10. The electronic device of claim 1, wherein at least second one of the first interlayer elements directly below the component has a first height greater than a second height of the at least one of the plurality of the first interlayer elements.

11. The electronic device of claim 8, further comprising an encapsulant covering the first connecting element and a portion of the encapsulant is disposed in a gap between the component and the chip.

12. The electronic device of claim 1, wherein the component comprises a decoupling capacitor.

13. An electronic device, comprising:
a chip having a pad;
a component disposed over the chip and having a terminal; and
a first interlayer element disposed over the pad and configured to guide a first connecting element to partially cover a lateral surface of the terminal.

14. The electronic device of claim 13, wherein a portion of the first connecting element is over a lower surface of the terminal, and the portion of the first connecting element has a width gradually decreasing in a direction facing away from the pad.

15. The electronic device of claim 14, wherein the first interlayer element is non-overlapping with the terminal in a top view perspective.

16. The electronic device of claim 14, further comprising a second interlayer element disposed below the terminal, wherein the first interlayer element is electrically connected to the second interlayer element through the pad.

17. An electronic device, comprising:
a chip having a pad and an insulating layer exposing an exposed portion of the pad;
a component disposed over the chip and comprising a terminal; and
a plurality of interlayer elements spaced apart from each other and disposed over the exposed portion of the pad to connect the terminal and the pad.

18. The electronic device of claim 17, wherein each of the interlayer elements has a tapered portion in contact with the pad.

19. The electronic device of claim 18, wherein each of the interlayer elements comprises a first conductive layer disposed between the terminal and the interlayer elements, and a portion of the first conductive layer is disposed along a lateral surface of the taper portion.

20. The electronic device of claim 18, further comprising a connecting element connecting the terminal and the interlayer elements, wherein a distance between a lateral surface of the connecting element and a lateral surface of the terminal increases in a direction toward a lower surface of the terminal.
